(19) United States
(12) Patent Application Publication
(10) Pub. No.: US 2026/0110715 A1
(43) Pub. Date: Apr. 23, 2026

(54) FAULT SENSOR

(71) Applicant: Cypress Semiconductor Corporation, San Jose, CA (US)

(72) Inventor: Dennis SEGUINE, Kalispell, MT (US)

(73) Assignee: Cypress Semiconductor Corporation, San Jose, CA (US)

(21) Appl. No.: 19/345,758

(22) Filed: Sep. 30, 2025

Related U.S. Application Data
(60) Provisional application No. 63/709,734, filed on Oct. 21, 2024.

(51) Int. Cl. G01R 19/252; G01R 19/25; G01R 31/52

(52) U.S. Cl. CPC G01R 19/252; G01R 19/2509; G01R 31/52

(57) ABSTRACT

According to some embodiments, a sensor includes an analog-to-digital converter (ADC) configured to sample a load current signal to generate load current data and a processor configured to perform a Fast Fourier Transform of the load current data to generate a frequency distribution comprising bins, sort the bins based on magnitude to generated sorted bins, determine a signal metric for a first subset of the sorted bins, determine a noise metric for a second subset of the sorted bins, and identify a fault condition based on the signal metric and the noise metric.

### CROSS-REFERENCE TO RELATED APPLICATIONS

This patent application relates to the commonly assigned U.S. provisional patent application Ser. No. 63/709,734, filed Oct. 21, 2024, entitled “Arc Fault Detection Using Analog Intelligence” which application is hereby incorporated herein by reference in its entirety.

### BACKGROUND

Electronic circuitry, wiring, and devices are susceptible to faults, such as arc faults (e.g., alternating current (AC) faults, direct current (DC) faults, etc.). Such faults can cause equipment damage or present safety risks. Different loads present different load profiles, making some fault detection difficult.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

According to some embodiments, a sensor comprises an analog-to-digital converter (ADC) configured to sample a load current signal to generate load current data and a processor configured to perform a Fast Fourier Transform of the load current data to generate a frequency distribution comprising bins, sort the bins based on magnitude to generated sorted bins, determine a signal metric for a first subset of the sorted bins, determine a noise metric for a second subset of the sorted bins, and identify a fault condition based on the signal metric and the noise metric.

According to some embodiments, a method for detecting a fault comprises sampling a load current signal to generate load current data, performing a Fast Fourier Transform of the load current data to generate a frequency distribution comprising bins, sorting the bins based on magnitude to generated sorted bins, determining a signal metric for a first subset of the sorted bins, determining a noise metric for a second subset of the sorted bins, and identifying a fault condition based on the signal metric and the noise metric.

According to some embodiments, a system for detecting a fault comprises means for sampling a load current signal to generate load current data, means for performing a Fast Fourier Transform of the load current data to generate a frequency distribution comprising bins, means for sorting the bins based on magnitude to generated sorted bins, means for determining a signal metric for a first subset of the sorted bins, means for determining a noise metric for a second subset of the sorted bins, and means for identifying a fault condition based on the signal metric and the noise metric.

According to some embodiments, a sensing system comprises a compensation amplifier configured to receive a load current signal, a frequency compensation resistor-capacitor network connected between an input of the compensation amplifier and an output of the compensation amplifier to generate a gain as a function of a frequency associated with the load current signal, an analog-to-digital converter (ADC) connected to the compensation amplifier and configured to generate load current data as a function of the gain and the load current signal, and a processor configured to perform a Fast Fourier Transform of the load current data to generate a frequency distribution comprising bins, sort the bins based on magnitude to generated sorted bins, determine a signal metric for a first subset of the sorted bins, determine a noise metric for a second subset of the sorted bins, and identify a fault condition based on the signal metric and the noise metric.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1 is a block diagram of a detector, such as an arc fault detector, in accordance with some embodiments.

FIG. 2A illustrates diagrams including signal and noise profiles, in accordance with some embodiments.

FIG. 2B illustrates a periodic signal frequency distribution, a noise signal frequency distribution, a sorted periodic signal frequency distribution, and a sorted noise signal frequency distribution, in accordance with some embodiments.

FIG. 3 is a flow diagram illustrating an example method for detecting a fault, such as an arc fault, in accordance with some embodiments.

FIG. 4 illustrates an exemplary embodiment of a computer-readable medium, in accordance with some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

It is to be understood that the following description of embodiments is not to be taken in a limiting sense. The scope of the present disclosure is not intended to be limited by the embodiments described hereinafter or by the drawings, which are taken to be illustrative only. The drawings are to be regarded as being schematic representations and elements illustrated in the drawings are not necessarily shown to scale. Rather, the various elements are represented such that their function and general purpose become apparent to a person skilled in the art.

All numerical values within the detailed description and the claims herein are modified by “about” or “approximately” the indicated value, and take into account experimental error and variations that would be expected by a person having ordinary skill in the art.

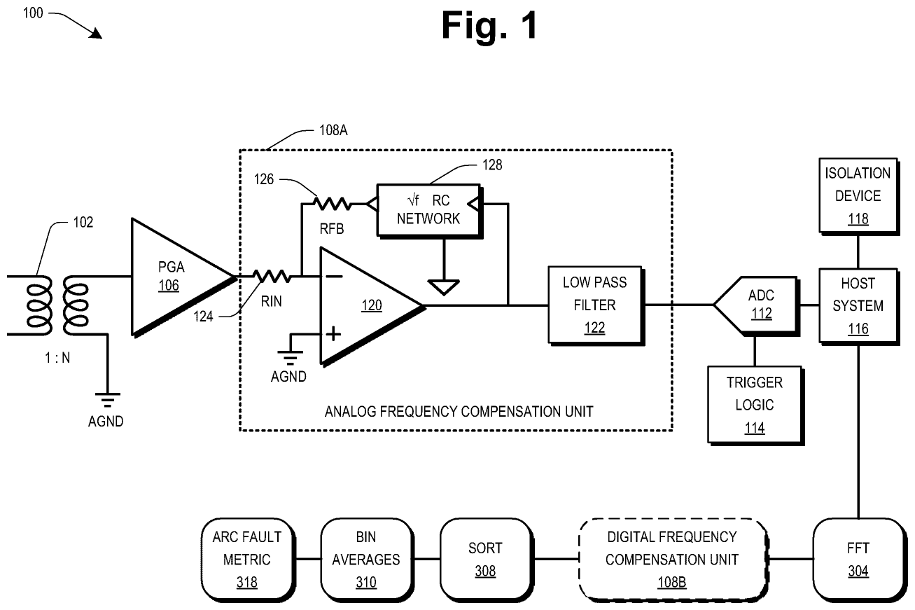

FIG. 1 is a block diagram of a detector 100, such as an arc fault detector, configured to detect direct current (DC) faults, in accordance with some embodiments. DC arc faults generate continuous broadband noise. The noise power generally follows the inverse of frequency (1/f). The noise voltage follows the inverse of the square root of the frequency (1/√f).

In some embodiments, the fault detector 100 comprises a current transformer 102 to provide load isolation and generate a load current signal representative of an AC load current signal on the primary side of the current transformer 102. For example, the load current may be generated by an inverter that uses a DC voltage source to generate an AC current. The switching signals and their harmonics (e.g., pulse width modulation (PWM) signals) used to control the inverter introduce a periodic component in the load current signal. The fault detector 100 comprises a programmable gain amplifier 106 connected to the current transformer 102 to amplify the load current signal and one of an analog frequency compensation unit 108A connected to the programmable gain amplifier 106 or a digital frequency compensation unit 108B to adjust the frequency profile of the load current signal. A noise component of the load current signal may be affected by the presence of a DC arc fault.

The fault detector 100 comprises an analog-to-digital converter (ADC) 112 for sampling the output of the analog frequency compensation unit 108A or the output of the PGA 106 if the digital frequency compensation unit 108B is employed. Trigger logic 114 is configured to control the ADC 112 during sampling intervals. The choice for using the analog frequency compensation unit 108A the digital frequency compensation unit 108B may depend on the computational capabilities of the fault detector 100. The use of the analog frequency compensation unit 108A facilitates the use of an ADC with less dynamic range and less complexity in the host system 116, potentially reducing cost.

In some embodiments, the ADC 112 is connected to a host system 116 to process the arc detection signals and control an isolation device 118 connected to a load served by the load current signal (i.e., on the primary side of the current transformer 102), such as a circuit breaker or e-fuse, based on an arc fault detection. The host system 116 may include a direct memory access (DMA) unit to allow the output of the ADC 112 to be read directly into a memory of the host system 116. In some embodiments, the host system 116 includes a processing unit, such as one or multiple processors, microprocessors, data processors, co-processors, application specific integrated circuits (ASICs), controllers, programmable logic devices, chipsets, field-programmable gate arrays (FPGAs), application specific instruction-set processors (ASIPs), system-on-chips (SoCs), central processing units (CPUs) (e.g., one or multiple cores), microcontrollers, and/or some other type of component that interprets and/or executes instructions and/or data. The host system 116 may be implemented as hardware (e.g., a microprocessor, etc.), a combination of hardware and software (e.g., a programmable system on a chip (PSoC™), an application specific integrated circuit (ASIC), etc.), and may include one or multiple memories (e.g., flash, DRAM, cache, etc.), etc.

In some embodiments, the analog frequency compensation unit 108A comprises a compensation amplifier 120 that receives the load current signal from the PGA 106 and a low pass filter 122. The gain of the compensation amplifier 120 is determined by an input resistor 124 and a feedback resistor 126 in series with a frequency compensation resistor-capacitor (RC) network 128 generates a compensation factor that varies with √f to compensate for the 1/√f nature of the noise. The low pass filter 122 has a cutoff frequency of about 200 kHz to reject noise and aliases. The gain of the programmable gain amplifier 106 may be varied depending on the particular implementation to increase performance.

In some embodiments, the host system 116 processes the output of the ADC 112 to identify an arc fault. The host system 116 performs a Fast Fourier Transform (FFT) 130 of the sampled load current signal to generate a frequency profile. Complex values of the FFT may be converted to magnitude squared values by summing the squares of the complex components or to magnitude values by taking the square root of the sum. If the digital frequency compensation unit 108B is employed, the host system 116 performs frequency compensation by multiplying the magnitude of each frequency bin in the FFT by a factor of √f to compensate for the 1/√f nature of the noise magnitude. In an embodiment where the value of each frequency bin is represented as a magnitude squared, the compensation factor would be 1/f. This approach reduces computational complexity by avoiding a square root on each bin value.

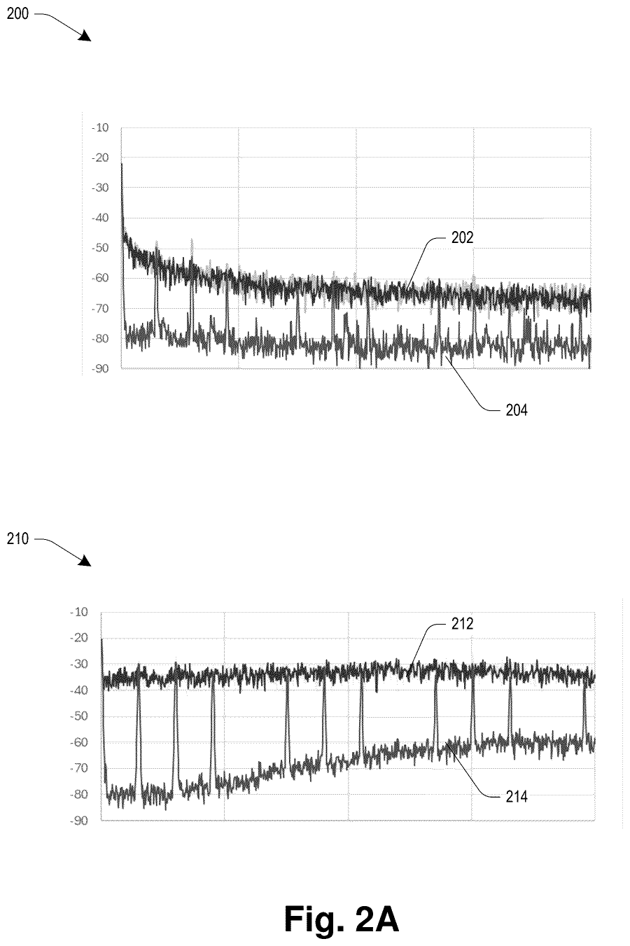

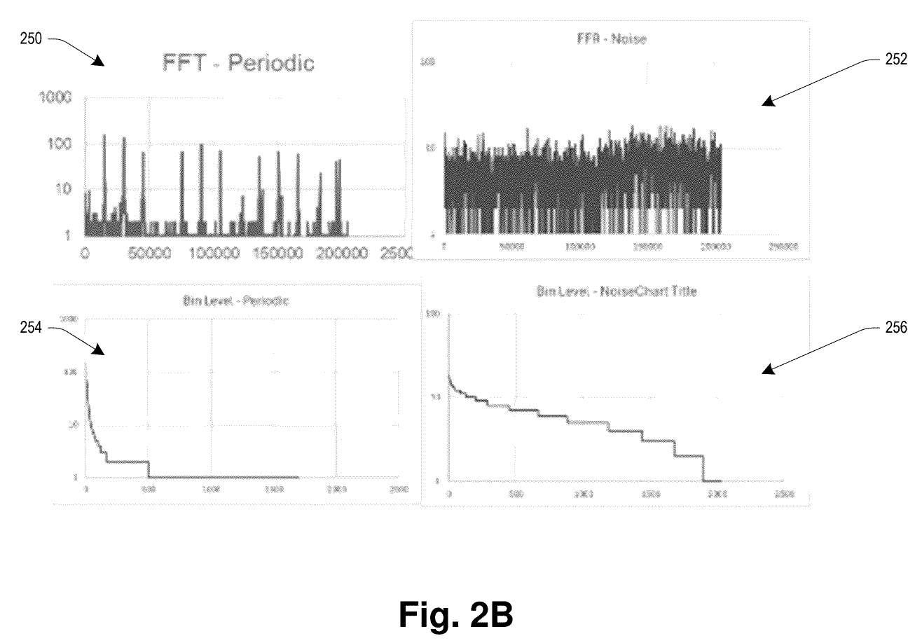

FIG. 2A illustrates diagrams 200, 210 including signal and noise profiles. The plot 202 represents the frequency spectrum of the combined periodic component and noise component, and the plot 204 represents the frequency spectrum of the periodic component. Note that the plot 202 exhibits an inverse frequency (1/√f) profile. FIG. 2B illustrates the signal and noise profiles after frequency compensation by the analog frequency compensation unit 108A or the digital frequency compensation unit 108B to apply a compensation gain of √f. The plot 212 represents the frequency spectrum of the combined periodic component and noise component, and the plot 214 represents the frequency spectrum of the periodic component. Note that the plot 212 is flattened after the frequency compensation making distinguishing between noise and signal more readily accomplished.

FIG. 2B illustrates a periodic signal frequency distribution 250 and a noise signal frequency distribution 252. Note that the periodic signal frequency distribution 250 includes higher peaks at the switching frequency and harmonics, while the noise signal frequency distribution 252 has a relatively flat profile after frequency compensation. The presence or absence of an arc fault is generally determined by the magnitude of the noise level.

FIG. 2B also illustrates a sorted periodic signal frequency distribution 254 and a sorted noise signal frequency distribution 256. Note that the sorted periodic signal frequency distribution 254 includes a relatively small number of higher peaks and falls to zero rather quickly, while the sorted noise signal frequency distribution 256 drops less significantly and less rapidly.

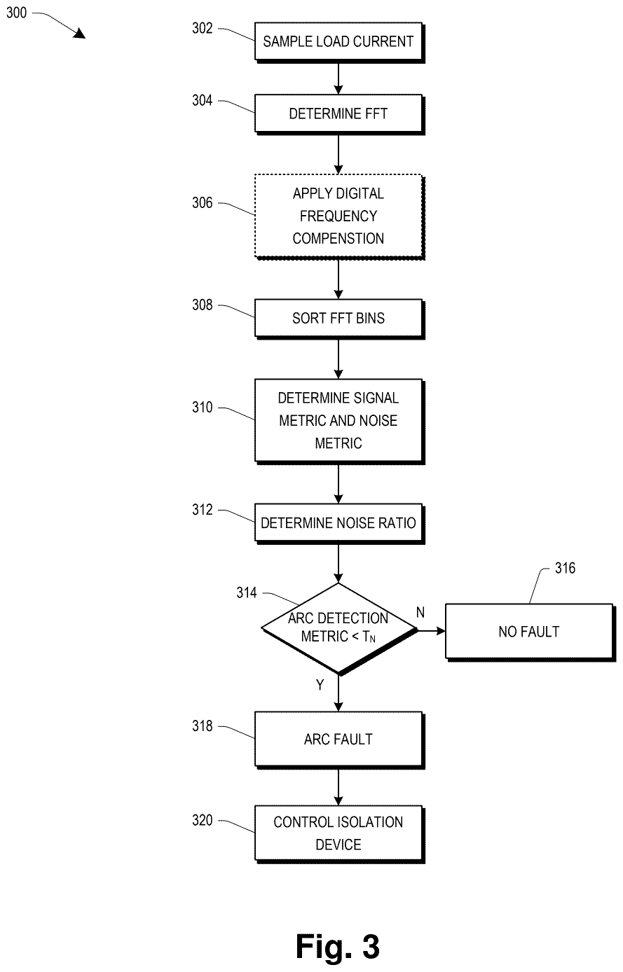

FIG. 3 is a flow diagram illustrating an example method 300 for detecting faults, such as arch faults, in accordance with some embodiments. At 302, the ADC 112 samples the load current signal, which includes the combined periodic and noise signals. At 304, the host system 116 determines an FFT to generate a combined periodic signal and noise frequency spectrum. If the digital frequency compensation unit 108B is used the √f gain is applied at 306 (optional). At 308, the host system 116 performs a sort operation to sort the frequency compensated bins by magnitude. In general, the periodic components caused by the inverter have higher magnitudes than the noise components, which have relatively flat gains across frequency. The host system 116 divides the sorted FFT spectrum into a first set of periodic bins (e.g., high magnitude bins) and a second set of noise bins that include the remaining bins. The number of pins in the periodic set may be around 5% of the bins and the number of bins in the noise bins may be the remaining 95%. The particular number of bins in each set may vary depending on the implementation.

At 310, the host system 116 determines a signal metric by averaging the magnitudes of the periodic bins and a noise metric by averaging the values of the noise bins. At 312, an arc detection ratio is determined by dividing the signal metric by the noise metric. At 314, the arc detection ratio is compared to a threshold. No fault condition is identified at 316 if the arc threshold is not violated, and an arc fault condition is identified at 318 if the arc threshold is violated. Responsive to the arc fault detection at 318, the isolation device 118 is controlled at 320. The host system 116 may trip the isolation device 118 to isolate the load.

The host detection algorithm compares the average of the dominant frequency levels in the periodic bins (i.e., inverter harmonics) to the average of the noise bins having higher frequency spectral levels and excluding inverter harmonics. In the case of a “clean” inverter, the noise level between harmonics in the periodic bins and the noise level in the noise bins is generally small relative to the levels of the harmonics, even though the higher frequency FFT bins have considerable gain applied to them. In the case of a DC arc fault, the noise magnitudes increase and can have values approaching those of the inverter harmonics. The arc threshold is set so that there is significant margin between the periodic/noise ratio for the inverter only and the periodic/noise ratio for the arc fault case. When there is no arc fault present, the average noise is low and the arc fault metric (periodic to noise ratio) is high. When there is an arc present the average noise is considerably higher, so that the arc fault metric is smaller.

The arc threshold is set at a value so that the presence of an arc is reliably detected and the lack of an arc has low risk of generating a false positive. In some embodiments, the change in the noise ratio with and without an arc is about at least twenty to one. There is some variation in the relative magnitudes of the arc detection metric in an arc detection and no arc depending on the number of bins in the periodic set versus the noise set. The number of bins in each set and the arc detection threshold may be varied depending on the specific implementation. The particular arc threshold may be set based on individual system characteristics and to balance the consequences false arc detections or missed arc detections.

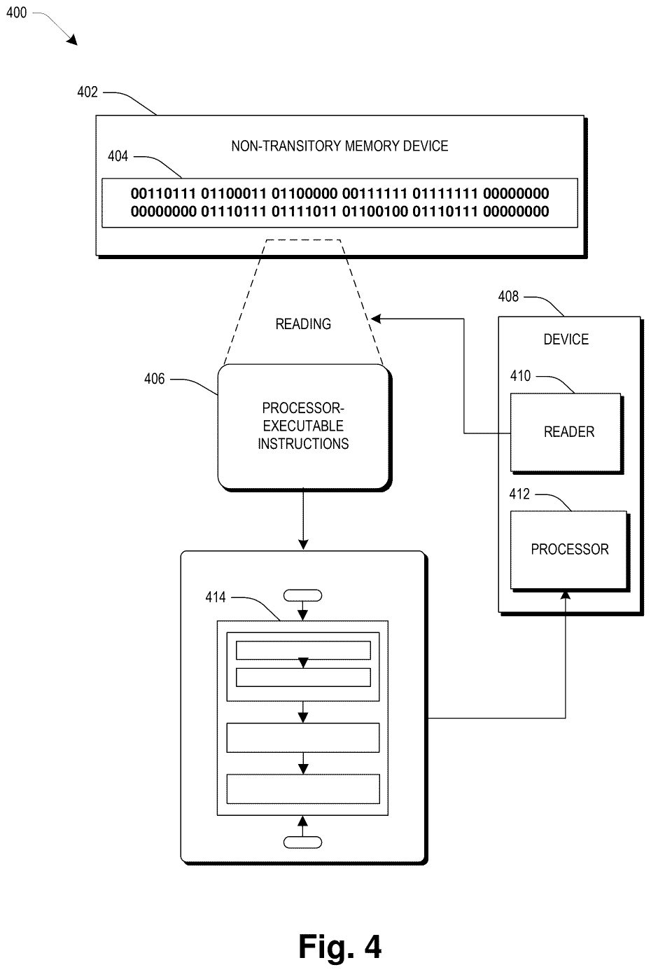

FIG. 4 illustrates an exemplary embodiment 400 of a computer-readable medium 402, in accordance with some embodiments. One or more embodiments involve a computer-readable medium comprising processor-executable instructions configured to implement one or more of the techniques presented herein. The embodiment 400 comprises a non-transitory computer-readable medium 402 (e.g., a CD-R, DVD-R, flash drive, a platter of a hard disk drive, etc.), on which is encoded computer-readable data 404. This computer-readable data 404 in turn comprises a set of processor-executable computer instructions 406 that, when executed by a computing device 408 including a reader 410 for reading the processor-executable computer instructions 406 and a processor 412 for executing the processor-executable computer instructions 406, are configured to facilitate operations according to one or more of the principles set forth herein. In some embodiments, the processor-executable computer instructions 406, when executed, are configured to facilitate performance of a method 414, such as at least some of the aforementioned method(s). In some embodiments, the processor-executable computer instructions 406, when executed, are configured to facilitate implementation of a system, such as at least some of the one or more aforementioned system(s). Many such computer-readable media may be devised by those of ordinary skill in the art that are configured to operate in accordance with the techniques presented herein.

The term “computer readable media” and/or the like may include communication media. Communication media typically embodies computer readable instructions or other data in a “modulated data signal” such as a carrier wafer or other transport mechanism and includes any information delivery media. The term “modulated data signal” may include a signal that has one or more of its characteristics set or changed in such a manner as to encode information in the signal. The term “computer readable media” may include communication media. Communication media typically embodies computer readable instructions or other data in a “modulated data signal” such as a carrier wafer or other transport mechanism and includes any information delivery media. The term “modulated data signal” may include a signal that has one or more of its characteristics set or changed in such a manner as to encode information in the signal.

According to some embodiments, a sensor comprises an analog-to-digital converter (ADC) configured to sample a load current signal to generate load current data and a processor configured to perform a Fast Fourier Transform of the load current data to generate a frequency distribution comprising bins, sort the bins based on magnitude to generated sorted bins, determine a signal metric for a first subset of the sorted bins, determine a noise metric for a second subset of the sorted bins, and identify a fault condition based on the signal metric and the noise metric.

According to some embodiments, the processor is configured to implement a frequency compensation unit to compensate the load current signal based on frequency by applying a gain factor to a bin based on a frequency associated with the bin.

According to some embodiments, the frequency compensation unit comprises a compensation amplifier configured to receive the load current signal and a frequency compensation resistor-capacitor network connected between an input of the compensation amplifier and an output of the compensation amplifier.

According to some embodiments, the frequency compensation unit comprises a low pass filter connected between the compensation amplifier and the ADC.

According to some embodiments, the sensor comprises a current transformer configured to generate the load current signal and a programmable gain amplifier connected to the current transformer and the compensation amplifier to amplify the load current signal.

According to some embodiments, the processor is configured to determine the signal metric by averaging the first subset of the sorted bins and determine the noise metric by averaging the second subset of the sorted bins.

According to some embodiments, the processor is configured to identify the fault condition responsive to a ratio of the signal metric to the noise metric violating a threshold.

According to some embodiments, a method for detecting a fault comprises sampling a load current signal to generate load current data, performing a Fast Fourier Transform of the load current data to generate a frequency distribution comprising bins, sorting the bins based on magnitude to generated sorted bins, determining a signal metric for a first subset of the sorted bins, determining a noise metric for a second subset of the sorted bins, and identifying a fault condition based on the signal metric and the noise metric.

According to some embodiments, the method comprises compensating the load current signal by applying a gain factor to a bin based on a frequency associated with the bin.

According to some embodiments, the method comprises using a compensation amplifier to generate the gain factor as a function of the frequency.

According to some embodiments, the method comprises using a frequency compensation resistor-capacitor network to generate the gain factor as a function of the frequency.

According to some embodiments, the method comprises amplifying the load current signal using a programmable gain amplifier connected to the compensation amplifier.

According to some embodiments, determining the signal metric comprises averaging the first subset of the sorted bins and determining the noise metric comprises averaging the second subset of the sorted bins.

According to some embodiments, identifying the fault condition comprises identifying the fault condition responsive to a ratio of the signal metric to the noise metric violating a threshold.

According to some embodiments, sorting the bins based on magnitude comprises sorting the bins based on a square of the magnitude to generate the sorted bins.

According to some embodiments, a sensing system comprises a compensation amplifier configured to receive a load current signal, a frequency compensation resistor-capacitor network connected between an input of the compensation amplifier and an output of the compensation amplifier to generate a gain as a function of a frequency associated with the load current signal, an analog-to-digital converter (ADC) connected to the compensation amplifier and configured to generate load current data as a function of the gain and the load current signal, and a processor configured to perform a Fast Fourier Transform of the load current data to generate a frequency distribution comprising bins, sort the bins based on magnitude to generated sorted bins, determine a signal metric for a first subset of the sorted bins, determine a noise metric for a second subset of the sorted bins, and identify a fault condition based on the signal metric and the noise metric.

According to some embodiments, the sensing system comprises a current transformer configured to generate the load current signal.

According to some embodiments, the sensing system comprises a programmable gain amplifier connected to the current transformer and configured to amplify the load current signal.

According to some embodiments, the processor is configured to determine the signal metric by averaging the first subset of the sorted bins and determine the noise metric by averaging the second subset of the sorted bins.

According to some embodiments, the processor is configured to identify the fault condition responsive to a ratio of the signal metric to the noise metric violating a threshold.

Various operations of embodiments are provided herein. In one embodiment, one or more of the operations described may constitute computer readable instructions stored on one or more computer readable media, which if executed by a computing device, will cause the computing device to perform the operations described. The order in which some or all of the operations are described should not be construed as to imply that these operations are necessarily order dependent. Alternative ordering will be appreciated by one skilled in the art having the benefit of this description. Further, it will be understood that not all operations are necessarily present in each embodiment provided herein. Also, it will be understood that not all operations are necessary in some embodiments.

Any aspect or design described herein as an “example” is not necessarily to be construed as advantageous over other aspects or designs. Rather, use of the word “example” is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

What is claimed is:

1. A sensor, comprising:
an analog-to-digital converter (ADC) configured to sample a load current signal to generate load current data; and
a processor configured to:
perform a Fast Fourier Transform of the load current data to generate a frequency distribution comprising bins;
sort the bins based on magnitude to generated sorted bins;
determine a signal metric for a first subset of the sorted bins;
determine a noise metric for a second subset of the sorted bins; and
identify a fault condition based on the signal metric and the noise metric.

2. The sensor of claim 1, wherein:
the processor is configured to implement a frequency compensation unit to compensate the load current signal based on frequency by applying a gain factor to a bin based on a frequency associated with the bin.

3. The sensor of claim 2, wherein:
the frequency compensation unit comprises:
a compensation amplifier configured to receive the load current signal; and
a frequency compensation resistor-capacitor network connected between an input of the compensation amplifier and an output of the compensation amplifier.

4. The sensor of claim 3, wherein:
the frequency compensation unit comprises:
a low pass filter connected between the compensation amplifier and the ADC.

5. The sensor of claim 3, comprising:
a current transformer configured to generate the load current signal; and
a programmable gain amplifier connected to the current transformer and the compensation amplifier to amplify the load current signal.

6. The sensor of claim 1, wherein:
the processor is configured to:
determine the signal metric by averaging the first subset of the sorted bins; and
determine the noise metric by averaging the second subset of the sorted bins.

7. The sensor of claim 1, wherein:
the processor is configured to identify the fault condition responsive to a ratio of the signal metric to the noise metric violating a threshold.

8. A method for detecting a fault, comprising:
sampling a load current signal to generate load current data;
performing a Fast Fourier Transform of the load current data to generate a frequency distribution comprising bins;
sorting the bins based on magnitude to generated sorted bins;
determining a signal metric for a first subset of the sorted bins;
determining a noise metric for a second subset of the sorted bins; and
identifying a fault condition based on the signal metric and the noise metric.

9. The method of claim 8, comprising:
compensating the load current signal by applying a gain factor to a bin based on a frequency associated with the bin.

10. The method of claim 9, comprising:
using a compensation amplifier to generate the gain factor as a function of the frequency.

11. The method of claim 9, comprising:
using a frequency compensation resistor-capacitor network to generate the gain factor as a function of the frequency.

12. The method of claim 10, comprising:
amplifying the load current signal using a programmable gain amplifier connected to the compensation amplifier.

13. The method of claim 8, wherein:
determining the signal metric comprises averaging the first subset of the sorted bins; and
determining the noise metric comprises averaging the second subset of the sorted bins.

14. The method of claim 8, wherein:
identifying the fault condition comprises identifying the fault condition responsive to a ratio of the signal metric to the noise metric violating a threshold.

15. The method of claim 8, wherein:
sorting the bins based on magnitude comprises sorting the bins based on a square of the magnitude to generate the sorted bins.

16. A sensing system, comprising:
a compensation amplifier configured to receive a load current signal;
a frequency compensation resistor-capacitor network connected between an input of the compensation amplifier and an output of the compensation amplifier to generate a gain as a function of a frequency associated with the load current signal;
an analog-to-digital converter (ADC) connected to the compensation amplifier and configured to generate load current data as a function of the gain and the load current signal; and
a processor configured to:
perform a Fast Fourier Transform of the load current data to generate a frequency distribution comprising bins;
sort the bins based on magnitude to generated sorted bins;
determine a signal metric for a first subset of the sorted bins;
determine a noise metric for a second subset of the sorted bins; and
identify a fault condition based on the signal metric and the noise metric.

17. The sensing system of claim 16, comprising:
a current transformer configured to generate the load current signal.

18. The sensing system of claim 17, comprising:
a programmable gain amplifier connected to the current transformer and configured to amplify the load current signal.

19. The sensing system of claim 16, wherein:
the processor is configured to:
determine the signal metric by averaging the first subset of the sorted bins; and
determine the noise metric by averaging the second subset of the sorted bins.

20. The sensing system of claim 16, wherein:
the processor is configured to identify the fault condition responsive to a ratio of the signal metric to the noise metric violating a threshold.
